(19) United States
(12) Patent Application Publication
(10) Pub. No.: US 2004/0174308 A1
(43) Pub. Date: Sep. 9, 2004

(54) Electricity detecting and testing device

(76) Inventor: Chung Shu Chang, Taichung (TW)

Correspondence Address: Chung Shu Chang, P.O. Box 63-99, Taichung, 406, TW

(21) Appl. No.: 10/382,406

(22) Filed: Mar. 4, 2003

(51) Int. Cl. G01R 1/00

(52) U.S. Cl. 343/703

(57) ABSTRACT

An electricity detecting and testing device includes a detecting device having an antenna to detect signals of either an electric field or an electromagnetic field, signal generating device for generating indicating signals, two conductors, one or more batteries, and a switch coupled to the batteries, to selectively couple the batteries to either the detecting device or the conductors. The conductors may be used to test whether the electric members have been damaged or not. The detecting device may be used to detect whether an electric current or energy has been supplied through the detected electric facilities or not.

### BACKGROUND OF THE INVENTION

1. Field of the Invention

The present invention relates to an electricity detecting and testing device, and more particularly to an electricity detecting and testing device that may be selectively used to detect electric current supplied to electric facilities, or to test electric facilities.

2. Description of the Prior Art

Typically, electricity or electrical energy is required to be supplied to the electric facilities, in order to energize the electric facilities.

For example, vehicles typically comprise four or more spark plugs that are coupled together to an electrical power source. The electrical power source may supply an electrical energy to the spark plugs, in order to energize the spark plugs in series or alternatively. When one or more spark plugs are damaged, or when the electrical energy may not be suitably supplied to the spark plugs, the spark plugs may not be suitably actuated, and thus the vehicles may not be suitably energized or actuated.

In order to detect or to test which of the sparks are damaged, the workers have to disengage the spark plugs from the vehicle engines, in order to test the sparks individually. In addition, a complicated facility may further be required to test or to detect whether the electric current or the electrical energy has been suitably supplied to the spark plugs or not.

Similarly, the typical Christmas light strings may comprise a number of light bulbs coupled together in series and/or in parallel to each other. When one or more light bulbs are damaged, some portions of the Christmas light strings or the whole Christmas light strings may be damaged. No suitable electrical testing facilities may be provided for the users to detect or to test which of the light bulbs or which portions of the Christmas light strings have been damaged.

The present invention has arisen to mitigate and/or obviate the afore-described disadvantages of the conventional electricity or electric current detecting or testing problems.

### SUMMARY OF THE INVENTION

The primary objective of the present invention is to provide an electricity detecting and testing device for selectively detecting whether electric current or electric energy has been suitably supplied to the electric facilities or not, or for testing whether the electric facilities have been damaged or not.

In accordance with one aspect of the invention, there is provided an electricity detecting and testing device comprising a detecting device including an antenna to detect signals of either an electric field or an electromagnetic field, and signal generating device for generating indicating signals, two separate conductors, at least one battery, and a switch coupled to the battery, to selectively couple the battery to either the detecting device or the conductors. The conductors may be provided to test or to examine whether the electric members have been damaged or not. The detecting device may be provided to test or to detect whether an electric current or electric energy has been supplied through the detected electric facilities or not.

The electricity detecting and testing device may further include a housing including an opening formed therein, the conductors being received in the opening of the housing.

The detecting device includes an amplifier coupled to the antenna to amplify the signals from the antenna, and/or includes a rectifier coupled to the antenna to rectify the signals from the antenna.

The generating device includes a buzzer to generate sounds, an oscillating circuit coupled to the buzzer, and/or a light member to generate indicating lights. The oscillating circuit may also be coupled to the light member.

Further objectives and advantages of the present invention will become apparent from a careful reading of the detailed description provided hereinbelow, with appropriate reference to the accompanying drawings.

### BRIEF DESCRIPTION OF THE DRAWINGS

FIG. 1 is a partial exploded view of an electricity detecting and testing device in accordance with the present invention;

FIG. 2 is a schematic view illustrating the electric circuit of the electricity detecting and testing device;

FIG. 3 is a schematic view illustrating a portion of the electric circuit of the electricity detecting and testing device;

FIG. 4 is a perspective view illustrating the operation of the electricity detecting and testing device;

FIG. 5 is a plan view illustrating the operation of the electricity detecting and testing device;

FIG. 6 is a schematic view similar to FIG. 3, illustrating the portion of the electric circuit of the electricity detecting and testing device;

FIG. 7 is a perspective view illustrating the operation of the electricity detecting and testing device;

FIG. 8 is a cross sectional view taken along lines 8-8 of FIG. 7; and

FIG. 9 is a perspective view illustrating the other application of the electricity detecting and testing device.

### DETAILED DESCRIPTION OF THE PREFERRED EMBODIMENT

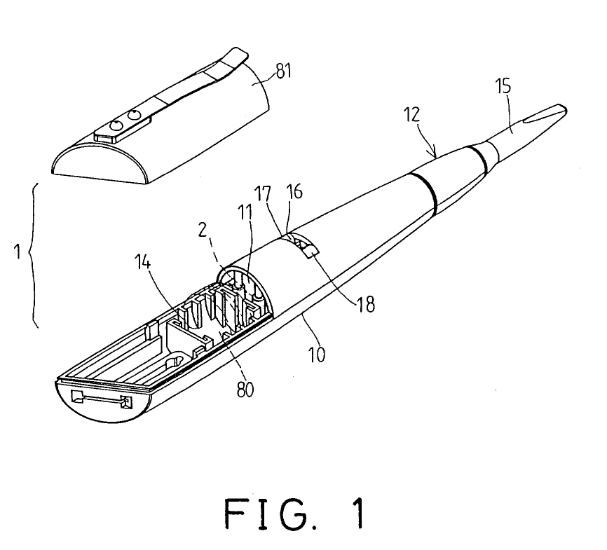

Referring to the drawings, and initially to FIG. 1, an electricity detecting and testing device in accordance with the present invention comprises a housing 10 that may be formed into a pen-shape or the like. The housing 10 includes a chamber 11 formed therein for receiving a circuit board 2 therein, and includes a space 14 formed therein and communicating with the chamber 11 thereof, to receive one or more batteries 80 therein. A cover 81 may be attached to the housing 10, for stably retaining the circuit board 2 and the batteries 80 in the housing 10.

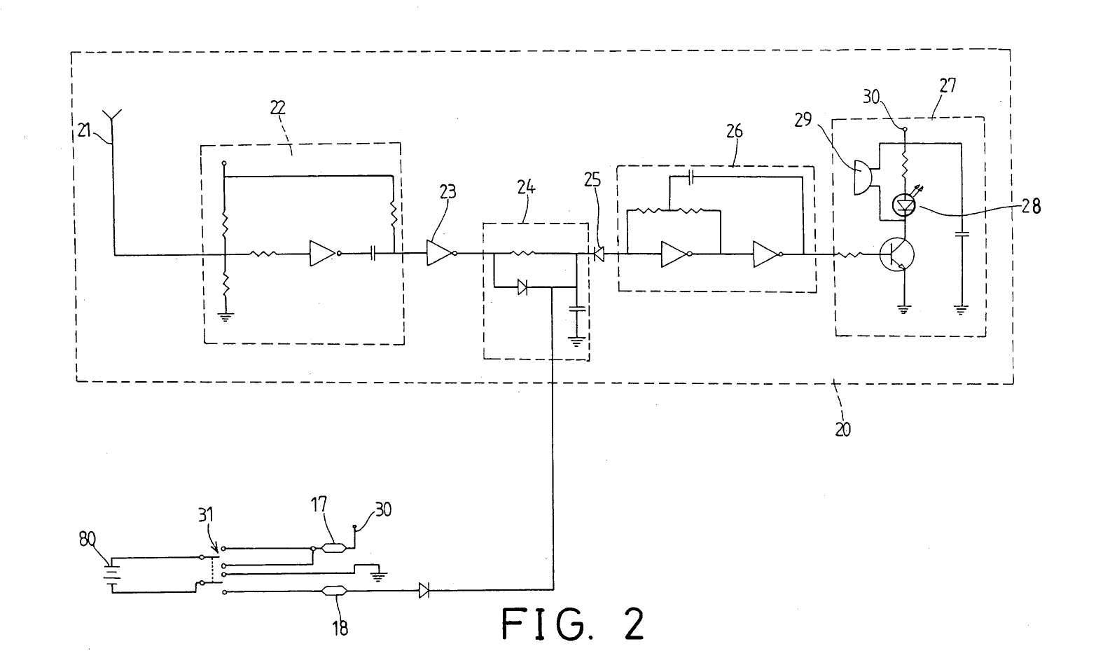

Referring next to FIG. 2, illustrated is an electric circuit provided on the circuit board 2. The electric circuit of the circuit board 2 includes a detecting circuit or device 20 having an antenna 21 disposed or received in the front portion 12 of the housing 10, for detecting the signals of the electric current or electric energy supplied or flown through an electric wire 90 (FIG. 4), or for detecting the signals of the electric field or the electromagnetic field generated by the electric current or electric energy flown through the electric wire 90.

The housing 10 may further include a tip 15 attached to the front portion 12 thereof, to indicate that the antenna 21 is disposed or received in the front portion 12 of the housing 10, or for guiding the users to detect the electric current or electric energy supplied or flown through the electric wire 90 with the front portion 12 of the housing 10 that has the tip 15 provided thereon. The tip 15 is preferably made of non-conductive materials, such as plastic materials or the like.

The electric circuit of the circuit board 2 includes an amplifier 22 coupled to the antenna 21, for receiving and amplifying the signals received from or via the antenna 21, an inverter 23 coupled to the amplifier 22 for such as buffering purposes, a rectifier 24 coupled to the inverter 23 for rectifying purposes, and a diode 25 coupled to the rectifier 24 for such as switching purposes. An oscillating circuit 26 and a driving circuit 27 are coupled to the diode 25.

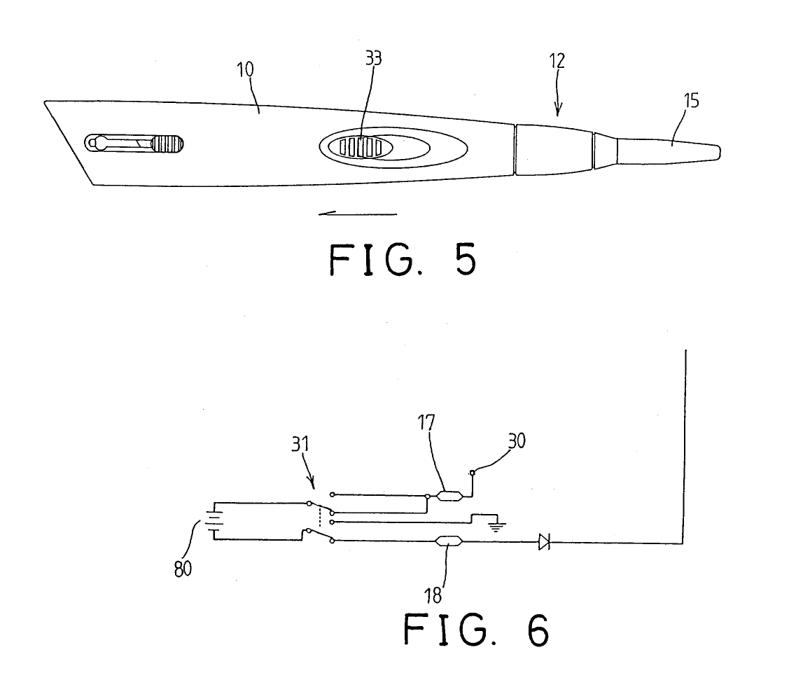

The driving circuit 27 may include a light member, such as a light emitting diode 28, and/or a buzzer 29 coupled to the oscillating circuit 26, for being selectively or alternatively energized to generate warning or indicating signals, such as lights and/or sounds. The electric circuit further includes a switch 31 coupled between the batteries 80 and the driving circuit 27, in order to selectively switch on or off the oscillating circuit 26 and the driving circuit 27. A knob 33 (FIGS. 4, 5) may be coupled to the switch 31, in order to actuate or operate the switch 31.

As shown in FIGS. 1, 2, 7 and 9, the housing 10 includes an opening 16 formed therein, and two conductors 17, 18 received in the opening 16 thereof and separated from each other. The conductors 17, 18 may be supported or coupled to the circuit board 2 (FIG. 8). One of the conductors 17 is coupled between a terminal 30 of the driving circuit 27 and the switch 31, and the other conductor 18 is coupled between the switch 31 and the rectifier 24. The conductors 17, 18 may also be selectively switched on or off by the switch 31.

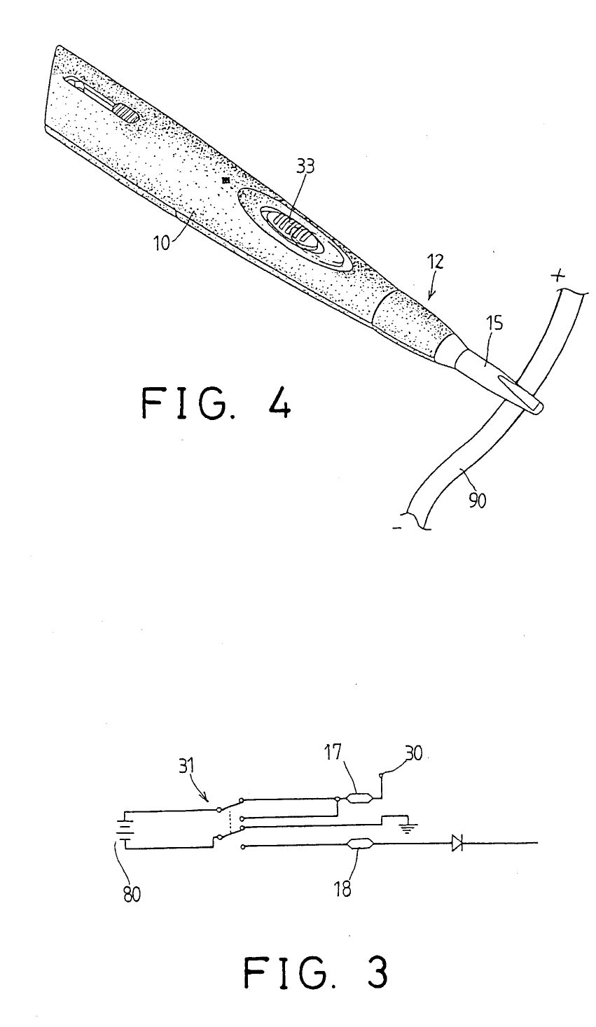

In operation, as shown in FIGS. 3 and 4, the switch 31 may be moved or actuated by or via the knob 33, in order to connect the batteries 80 to the oscillating circuit 26 and the driving circuit 27. At this moment, when the antenna 21 of the detecting device 20 detects one or more signals of such as the electric field or the electromagnetic field generated by the electric current or electric energy flown through the electric wire 90, the light emitting diode 28, and/or the buzzer 29 may be actuated to generate lights and/or sounds, and thus to indicate that the electric current or electric energy do flow through the electric wire 90.

On the contrary, when no electric current or electric energy flows through the electric wire 90, or when the antenna 21 of the detecting device 20 detects no signals from the electric wire 90, the light emitting diode 28, and/or the buzzer 29 will not be actuated or energized, in order to indicate that no electric current or electric energy is flown through the electric wire 90.

For example, the detecting device 20 may be used to detect whether the electrical energy has been suitably supplied to the spark plugs of the vehicles or not, or to detect whether the electrical energy has been suitably supplied to the light members of the typical Christmas light strings or not.

As shown in FIGS. 5-8, the switch 31 may also be moved or actuated by or via the knob 33, in order to selectively connect the batteries 80 to the conductors 17, 18 and the oscillating circuit 26 and the driving circuit 27.

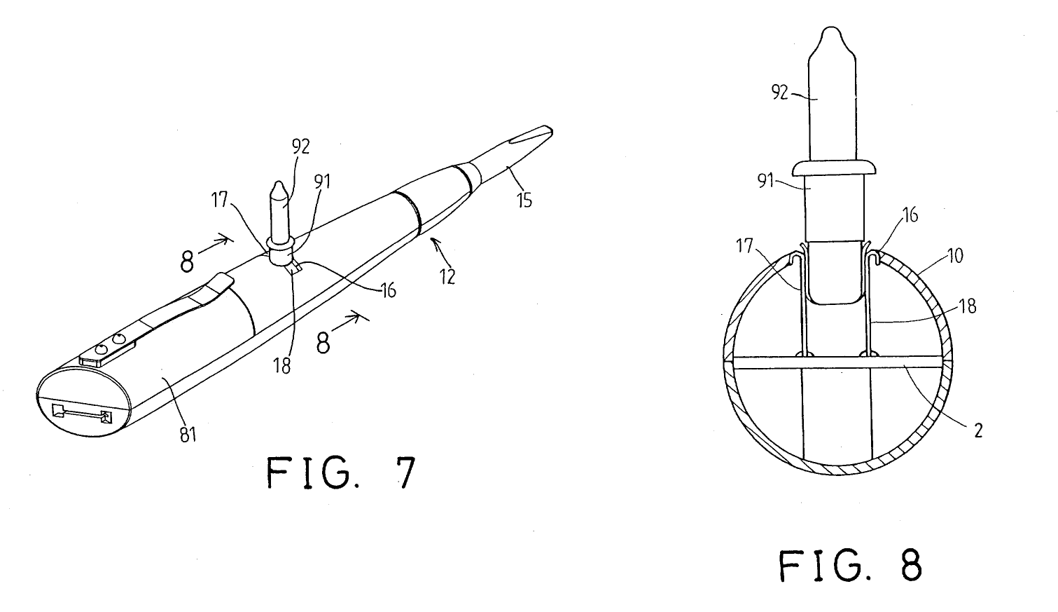

As best shown in FIGS. 7 and 8, a base 91 of a light member 92 may be engaged into the opening 16 of the housing 10 and engaged with the conductors 17, 18. If the light member 92 is damaged, the conductors 17, 18 will not be electrically coupled together by the light member 92. On the contrary, if the light member 92 has not been damaged, the conductors 17, 18 will be electrically coupled together by the light member 92, the light emitting diode 28, and/or the buzzer 29 may be actuated to generate lights and/or sounds, and thus to indicate that the light member 92 is a good one. The conductors 17, 18 may thus be used to detect whether the electrical energy has been suitably supplied to the light bulbs of the typical Christmas light strings or not.

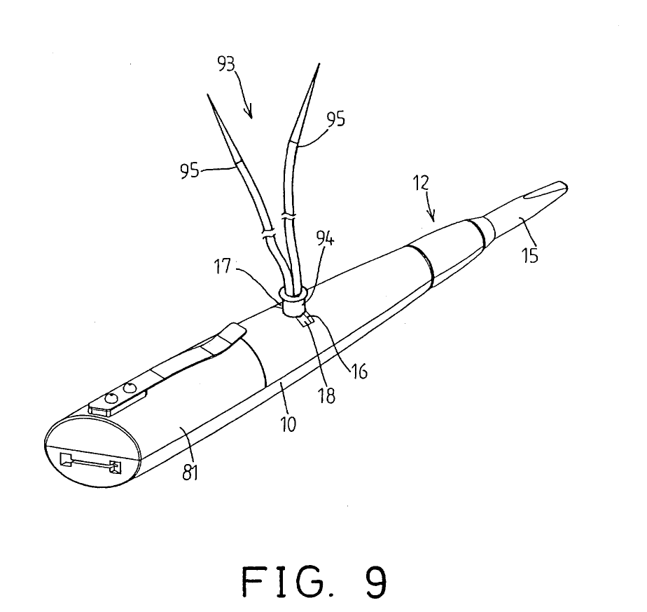

Similarly, as shown in FIG. 9, a testing member 93 may include a base 94 engaged into the opening 16 of the housing 10 and engaged with the conductors 17, 18, and one or more probes 95 coupled to the base 94 in order to detect or to test various electric facilities whether the electric facilities have been damaged or not. For example, the conductors 17, 18 will be electrically coupled together by the testing member 93 when the electric facilities are not damaged, and will not be electrically coupled together by the testing member 93 when the electric facilities are damaged. Accordingly, the electric facilities may be easily and quickly tested or examined whether they have been damaged or not.

Accordingly, the electricity detecting and testing device in accordance with the present invention may be used for selectively detecting whether electric current or electric energy has been suitably supplied to the electric facilities or not, or for testing whether the electric facilities have been damaged or not.

Although this invention has been described with a certain degree of particularity, it is to be understood that the present disclosure has been made by way of example only and that numerous changes in the detailed construction and the combination and arrangement of parts may be resorted to without departing from the spirit and scope of the invention as hereinafter claimed.

I claim:

1. An electricity detecting and testing device comprising:
a detecting device including an antenna to detect signals of either an electric field or an electromagnetic field, and signal generating means for generating indicating signals,
two separate conductors,
at least one battery, and
a switch coupled to said at least one battery, to selectively couple said at least one battery to either said detecting device or said conductors,
said conductors being provided for testing whether an electric member is damaged or not.

2. The electricity detecting and testing device as claimed in claim 1 further comprising a housing including an opening formed therein, said conductors being received in said opening of said housing.

3. The electricity detecting and testing device as claimed in claim 1, wherein said detecting device includes an amplifier coupled to said antenna to amplify the signals from said antenna.

4. The electricity detecting and testing device as claimed in claim 1, wherein said detecting device includes a rectifier coupled to said antenna to rectify the signals from said antenna.

5. The electricity detecting and testing device as claimed in claim 1, wherein said generating means includes a buzzer to generate sounds.

6. The electricity detecting and testing device as claimed in claim 5, wherein said generating means includes an oscillating circuit coupled to said buzzer.

7. The electricity detecting and testing device as claimed in claim 1, wherein said generating means includes a light member to generate indicating lights.

8. The electricity detecting and testing device as claimed in claim 7, wherein said generating means includes an oscillating circuit coupled to said light member.
